(19) United States
(12) Patent Application Publication
(10) Pub. No.: US 2009/0321833 A1
(43) Pub. Date: Dec. 31, 2009

(54) VERTICAL PROFILE FinFET GATE FORMED VIA PLATING UPON A THIN GATE DIELECTRIC

(75) Inventors: Veeraraghaven S. Basker, Schenectady, NY (US); Hariklia Deligianni, Tenafly, NJ (US); Toshiharu Furukawa, Essex Junction, VT (US); Steven J. Holmes, Guilderland, NY (US); David V. Horak, Essex Junction, VT (US); Charles W. Koburger, III, Delmar, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/145,616

(22) Filed: Jun. 25, 2008

(51) Int. Cl. H01L 29/78; H01L 21/336

(52) U.S. Cl. 257/365; 438/283; 257/E29.264; 257/E21.421

(57) ABSTRACT

Methods of making vertical profile FinFET gate electrodes via plating upon a thin gate dielectric are disclosed. In one embodiment, a method for forming a transistor, comprises: providing a semiconductor topography comprising a semiconductor substrate and a semiconductor fin structure extending above the substrate; forming a gate dielectric across exposed surfaces of the semiconductor topography; patterning a mask upon the semiconductor topography such that only a select portion of the gate dielectric is exposed that defines where a gate electrode is to be formed; and plating a metallic material upon the select portion of the gate dielectric to form a gate electrode across a portion of the fin structure.

### BACKGROUND OF THE INVENTION

1. Field of the Invention

This invention relates to semiconductor fabrication, and particularly to forming a vertical profile FinFET gate having metallic spacers formed via plating surfaces of a thin gate dielectric exposed by a patterned mask.

2. Description of Background

Integrated circuits often employ active devices known as transistors such as field effect transistors (FET's). A current integrated circuit FET includes a silicon-based substrate comprising a pair of impurity regions, i.e., source and drain junctions, spaced apart by a channel region. A gate electrode is dielectrically spaced above the channel region of the silicon-based substrate. The junctions can comprise dopants which are opposite in type to the dopants residing within the channel region interposed between the junctions. An interlevel dielectric can be disposed across the FET's of an integrated circuit to isolate the gate areas and the junctions from interconnect lines which overlie the FET's. Ohmic contacts can be formed through the interlevel dielectric to the gate areas and/or junctions to couple them to the overlying interconnect lines.

There are ongoing efforts to reduce the size of FET's to meet the high demand for increased device performance and increased circuit density. However, reducing the size of FET's undesirably increases the cost and difficulty of manufacturing those devices. A special type of FET known as a “finFET” has been developed as a type of device that will enable continuing FET size reduction and increased device performance. The body of a finFET is formed from a structure referred to as a “fin”, which extends vertically above the silicon-based substrate. The source and drain junctions are formed in the fin. The gate electrode of a finFET is formed across a central channel region of the fin and adjacent to one or more sides of the fin. The formation of the gate electrode can entail depositing a conductive layer across the fin and the substrate, patterning a photoresist mask using photolithography across the conductive layer, and etching (e.g., reactive ion etching (RIE)) regions of the conductive layer not protected by the mask to define the gate electrode.

Unfortunately, the overall resolution of the photolithography process used to form the gate electrodes of finFET's is limited. This overall resolution depends on parameters such as the properties of the photoresist and the resolution of the optical lithography system, i.e., the ability to form a resolvable image pattern on the semiconductor topography. Also, problems with the etch technique can occur. For example, the highly anisotropic nature of RIE can compromise its selectivity and can damage the surface of the material being etched. These limitations of the photolithography and etching processes can be exacerbated as the density of the finFET's is increased. As a result, the finFET gates are very difficult to form in accordance with design specifications.

### SUMMARY OF THE INVENTION

The shortcomings of the prior art are overcome and additional advantages are provided through the provision of vertical profile finFET gates formed via plating upon a thin gate dielectric. In an embodiment, a method for forming a transistor comprises: providing a semiconductor substrate, and a semiconductor fin structure extending above the substrate; forming a gate dielectric across exposed surfaces of the semiconductor topography; patterning a mask upon the semiconductor topography such that only a select portion of the gate dielectric is exposed that defines where a gate electrode is to be formed; and plating a metallic material upon the select portion of the gate dielectric to form a gate electrode across a portion of the fin structure.

In one embodiment, a transistor comprises: a semiconductor fin structure extending above a semiconductor substrate and comprising source and drain junctions; and a plated gate electrode extending across a portion of the fin structure, the gate electrode being in direct contact with a gate dielectric interposed between the gate electrode and the fin structure.

In another embodiment, a pair of transistors comprises: a pair of semiconductor fin structures spaced apart above a semiconductor substrate, each fin structure comprising source and drain junctions; and a single plated gate electrode extending across and between portions of the fin structures, the gate electrode being in direct contact with a gate dielectric interposed between the gate electrode and the fin structures.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1-4 and 5(a), 6(a), 7(a), 8(a), and 9(a) depict perspective views of a semiconductor substrate and the formation of dual finFET's thereon in accordance with an embodiment; and

FIGS. 5(b), 6(b), 7(b), 8(b), and 9(b) depict top plan views taken through mid-sections of the semiconductor topographies depicted in FIGS. 5(a), 6(a), 7(a), 8(a), and 9(a), respectively.

The detailed description explains the preferred embodiments of the invention, together with advantages and features, by way of example with reference to the drawings.

### DETAILED DESCRIPTION OF THE INVENTION

Methods are described for forming a finFET by plating a gate electrode upon surfaces of a gate dielectric exposed by a patterned mask. The method described herein avoids the problems associated with lithographically patterning and etching the finFET gate electrode. For example, due to the relatively low selectivity of RIE, long etch times can be required to perform RIE patterning of the gate electrode, which can undesirably introduce unacceptable linewidth variations to the gate electrode. Plating the gate electrode instead of etching it can provide for the formation of a very uniform gate electrode having a highly vertical profile.

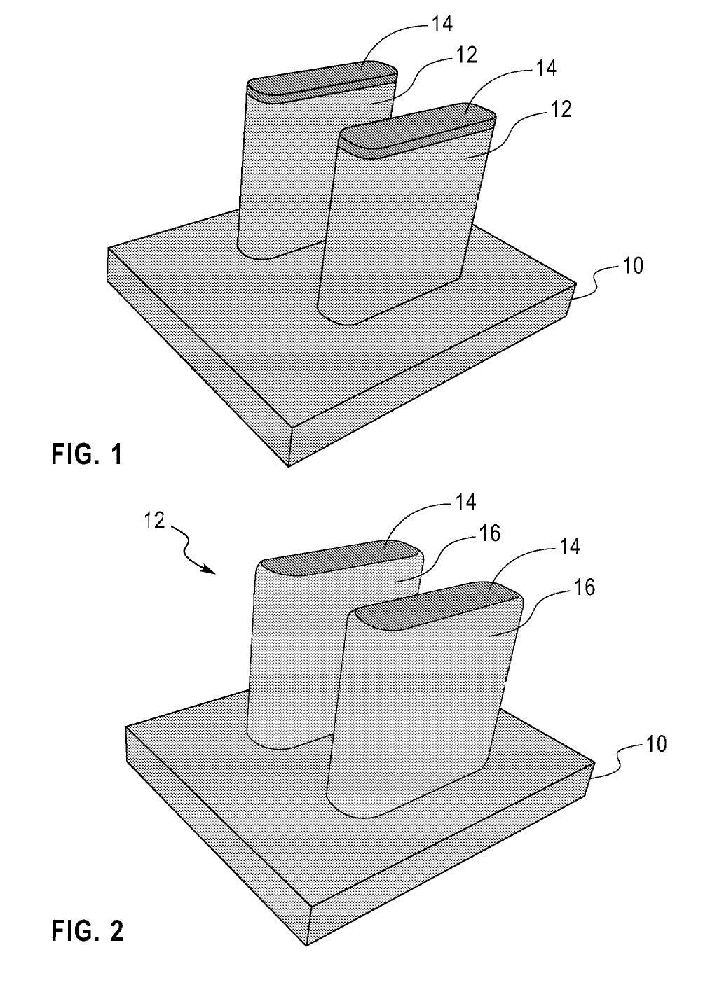

FIGS. 1-9(b) illustrate an exemplary embodiment of a method for forming dual finFET's comprising a single gate electrode. Dual finFET's can be employed for applications such as inverters or where multiple fins are gated in parallel to carry additional current. It is understood that a single finFET comprising a single gate electrode or a plurality of finFET's could alternatively be formed in a similar manner. First, as depicted in FIG. 1, a pair of fin structures 12 laterally spaced apart from each other is formed above a semiconductor substrate 10 comprising a semiconductor material such as single crystalline silicon or germanium that has been lightly doped with n-type or p-type dopants. The fin structures 12 can comprise a semiconductor material such as single-crystal silicon, germanium, or both silicon and germanium. A dielectric pad 14, such as a nitride pad (e.g., Si₃N₄), can optionally be formed upon the upper surfaces of the fin structures 12 to act as a protective cap during subsequent etching steps. The fin structures 12 and the dielectric pad 14 can be formed by depositing a semiconductor material and subsequently a dielectric material (e.g., by chemical vapor deposition) upon substrate 10, followed by patterning the semiconductor material and the dielectric material using a lithography technique and an etch technique, e.g., a dry, plasma etch. An alternative formation process would involve depositing a dielectric material upon a semiconductor material and using a lithography technique and an etch technique to form fins structures 12 and substrate 10 from the same semiconductor material.

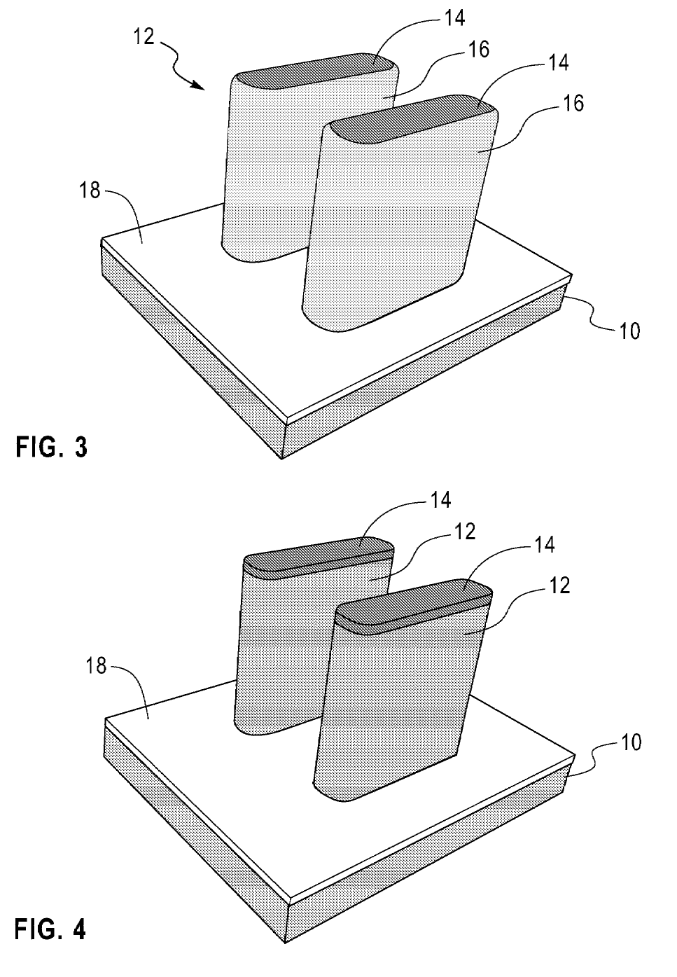

Turning to FIG. 2, dielectric spacers 16 can subsequently be formed upon the sidewalls of the fin structures 12. This formation of the spacers 16 involves depositing a dielectric layer, such as a silicon nitride (e.g., Si₃N₄), across the semiconductor substrate 10 and the fin structures 12 and subsequently removing portions of the dielectric layer using an anisotropic etch such as RIE. The dielectric pad 14 can protect the top of fin structures 12 from being removed during the anisotropic etch. As shown in FIG. 3, an oxide (e.g., SiO₂) layer 18 can thereafter be thermally grown upon semiconductor substrate 10 while dielectric spacers 16 inhibit the growth of the oxide upon the sidewalls of the semiconductor fin structures 12. The duration of the thermal growth can be selected to terminate when the thickness of the oxide layer 18 is sufficient to prevent plating upon the substrate 10 in ensuing steps. For example, the oxide layer 18 can have a thickness of about 6 nanometers (nm) to about 200 nm, more specifically about 10 nm to about 20 nm. As depicted in FIG. 4, the dielectric spacers 16 can then be selectively removed using, for example, a wet etch process. Unless it is desired to form triple-gated FET's, it is desirable to minimize overetch of the spacers 16 to ensure that at least a portion of the dielectric pads 14 remain intact on the upper surfaces of the fin structures 12. Alternatively, if the dielectric spacers 16 comprise silicon nitride, a relatively thick oxide could be used as the dielectric pads 14 to enable more overetch of the silicon nitride dielectric spacers 16.

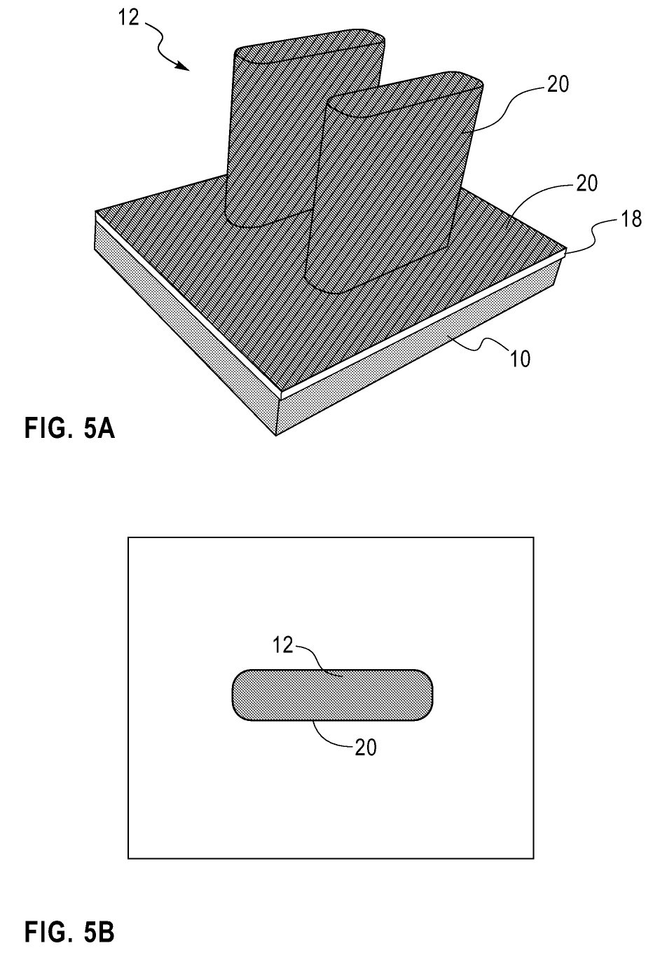

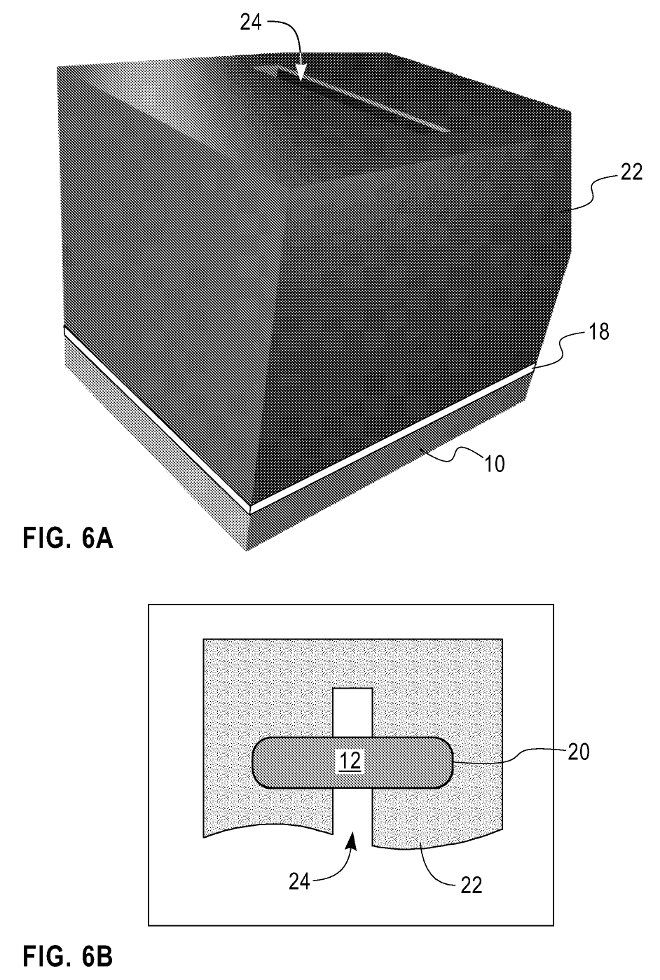

As illustrated in FIGS. 5(a) and 5(b), after the removal of the dielectric spacers 16, a gate dielectric 20 such as SiO₂ can be deposited (e.g., by chemical vapor deposition) across the exposed surfaces of the oxide layer 18 and the fin structures 12. The thickness of the gate dielectric 20 is desirably thin enough to allow plating to subsequently occur upon the surfaces of the gate dielectric 20. For example, the gate dielectric 20 can have a thickness of about 0.7 nm to about 3.5 nm, more specifically about 0.9 nm to about 1.1 nm. As depicted in FIGS. 6(a) and 6(b), a mask 22 can subsequently be patterned upon the semiconductor topography of FIG. 5(a). The mask 22 can form a mold-like structure comprising a slot 24 for exposing a select portion of the gate dielectric 20 to define where an ensuing gate electrode is to be formed. The mask 22 can comprise, for example, photoresist patterned using photolithography, a hardmask patterned using photolithography and an etch technique, or a multi-layer resist (MLR) structure formed using MLR technology. The mask 22 desirably has straight, smooth sidewalls and is cleared from the sidewalls of the fin structures 12.

A metallic material can be electroplated “through” the exposed surfaces of the gate dielectric 20 such that the slot 24 in the mask 22 is filled. The plating can be performed for a period of time sufficient to fill small spaces and to allow the metallic material to meet across spaces between adjacent fins to form continuous lines. As used herein, “metallic” refers to any material comprising metal including pure metals and alloys of metals. Examples of suitable metallic materials include, but are not limited to, Al, Co, Cr, Fe, Ir, Hf, Mg, Mo, Mn, Ni, Pd, Pt, La, Os, Nb, Rh, Re, Ru, Sn, Ta, Ti, V, W, Y, Zr, and alloys of the foregoing metals.

The electroplating can be performed by immersing the semiconductor topography shown in FIG. 6(a) in a bath comprising an electrolyte such as one or more metal salts dissolved in an aqueous solution. The concentration of the metal salt in the aqueous solution can range from about 0.01 millimolar (mM) to about 100 mM, more specifically about 0.1 mM to about 0.5 mM, and even more specifically about 0.01 mM to about 0.1 mM. A current can be applied to the semiconductor substrate 10 to cause the semiconductor topography to act as an anode that attracts the metal ions in the aqueous solution.

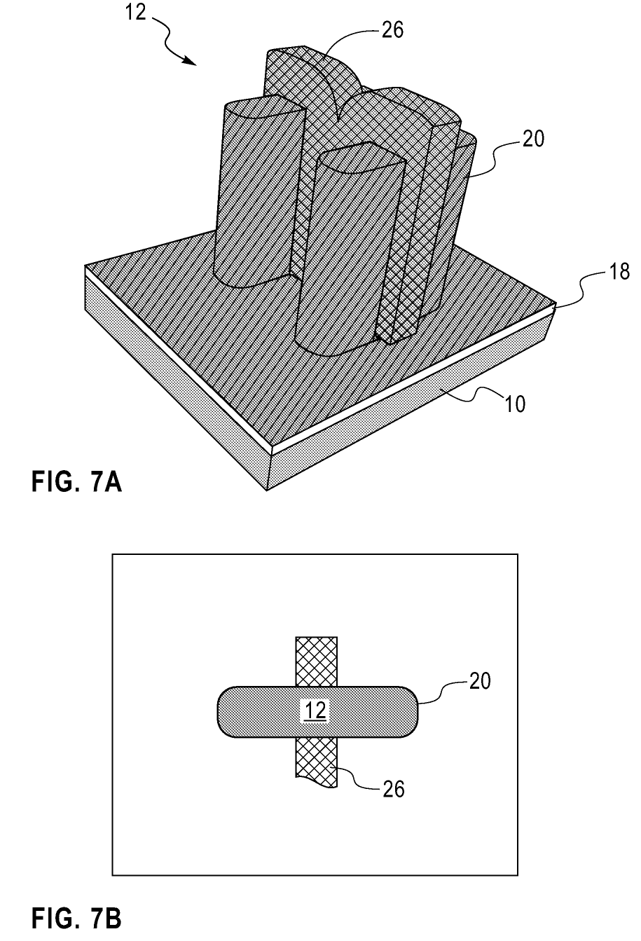

After the electroplating process is terminated by removing the semiconductor topography from the plating bath and rinsing it with water, the mask 22 can be stripped to reveal the gate electrode 26 shown in FIGS. 7(a) and 7(b). The gate electrode 26 extends across central regions of the fin structures 12 and adjacent to the sidewalls of those central regions, thus forming a contiguous gate upon and between the pair of closely spaced fin structures 12.

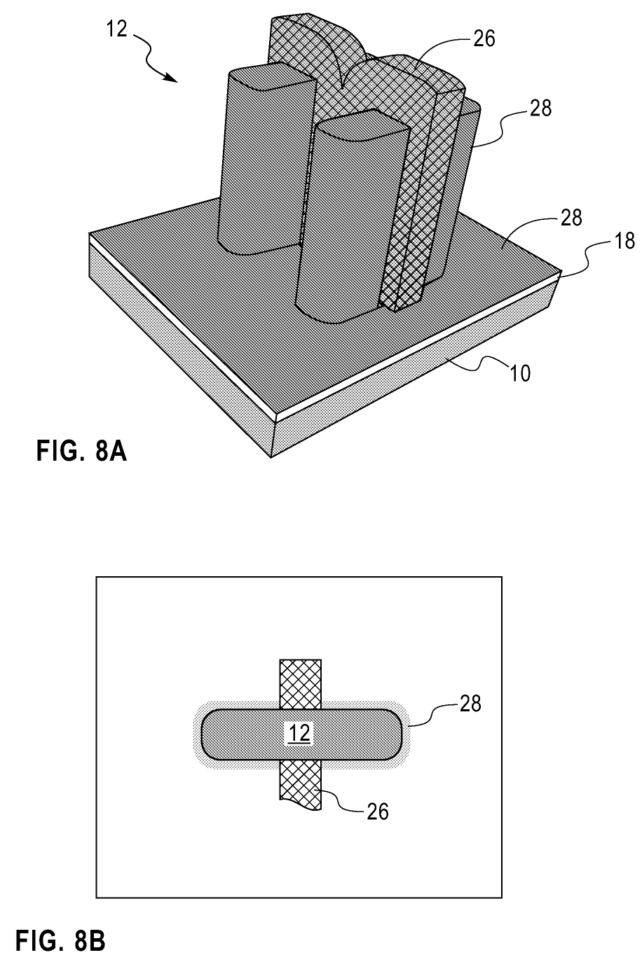

Turning to FIGS. 8(a) and 8(b), an additional oxide layer 28 can be selectively deposited upon the exposed surfaces of the gate dielectric 20 using a liquid phase deposition (LPD) process. The oxide in the gate dielectric 20 can serve as a bonding site for the LPD oxide, e.g., LPD-SiO₂. LPD can be performed by immersing the semiconductor topography shown in FIG. 7(a) in a supersaturated hydrofluosilicic acid (H₃SiF₆). The supersaturated hydrofluosilicic acid can be produced by adding aqueous boric acid (H₃BO₃) to a saturated hydrofluosilicic acid until a precipitate is produced. The precipitate can be adsorbed by the exterior oxide surface of the gate dielectric 20 to form the LPD oxide layer 28. The saturated hydrofluosilicic acid can be produced by adding SiO₂ powder to a hydrofluoric acid base until a solution at maximum equilibrium is formed. The thickness of the resulting LPD oxide layer 28 can be sufficient to prevent plating upon its surfaces. For example, the thickness of the LPD oxide layer 28 can be about 2.0 nm to about 10.0 nm, more specifically about 2.5 nm to about 3.5 nm. Lightly doped drain regions (not shown) that are self-aligned to the sidewalls of the gate electrode 26 can be implanted into the semiconductor fin structures 12 before or after the formation of the LPD oxide layer 28.

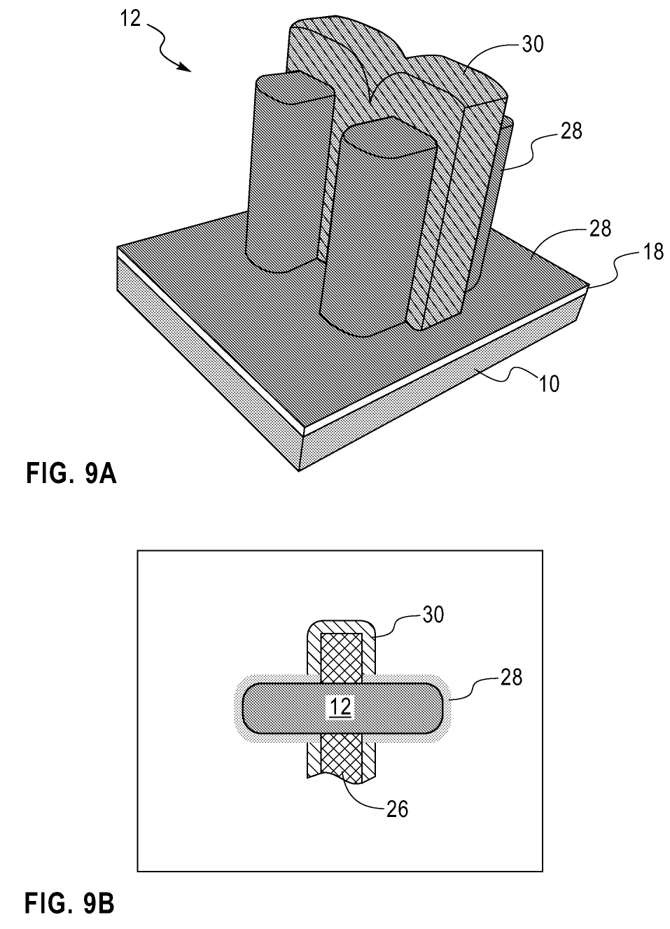

Subsequent to forming the LPD oxide layer 28, the electroplating process can be repeated to plate additional metallic material 30 upon the surfaces of the gate electrode 26, as depicted in FIGS. 9(a) and 9(b). The metallic material 30 being plated in this step can be the same or a different material as that present in the gate electrode 26. The LPD oxide layer 28 serves to prevent plating in all areas except upon the surfaces of the gate electrode 26. The lateral overgrowth of the plated metallic material 30 can form metallic spacers laterally adjacent to the sidewalls of the gate electrode 26.

Source/drain junctions that are self-aligned to the sidewall surfaces of the metallic material 30 (i.e., the spacers) can subsequently be implanted into the semiconductor fin structures 12 to complete the formation of the finFET devices. In the case of NFET's, the source/drain junctions can be implanted with n-type dopants, whereas in the case PFET's, the source/drain junctions can be implanted with p-type dopants. Examples of n-type dopants include, but are not limited to, arsenic and phosphorus, and an example of a p-type dopant includes, but is not limited to, boron. It is to be understood that both NFET and PFET devices can be formed within different fin structures 12 to form a CMOS (complementary metal-oxide semiconductor) circuit. Contacts also can be formed to the gate electrode 26 coated with metallic material 30, and to the source/drain junctions (i.e., the fin structures 12) to electrically contact the finFET transistors to overlying interconnect levels of the integrated circuit.

As used herein, the terms “a” and “an” do not denote a limitation of quantity but rather denote the presence of at least one of the referenced items. Moreover, ranges directed to the same component or property are inclusive of the endpoints given for those ranges (e.g., “about 5 wt % to about 20 wt %,” is inclusive of the endpoints and all intermediate values of the range of about 5 wt % to about 20 wt %). Reference throughout the specification to “one embodiment”, “another embodiment”, “an embodiment”, and so forth means that a particular element (e.g., feature, structure, and/or characteristic) described in connection with the embodiment is included in at least one embodiment described herein, and might or might not be present in other embodiments. In addition, it is to be understood that the described elements may be combined in any suitable manner in the various embodiments. Unless defined otherwise, technical and scientific terms used herein have the same meaning as is commonly understood by one of skill in the art to which this invention belongs.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method for forming a transistor, comprising:
providing a semiconductor topography comprising a semiconductor substrate and a semiconductor fin structure extending above the substrate;
forming a gate dielectric across exposed surfaces of the semiconductor topography;
patterning a mask upon the semiconductor topography such that only a select portion of the gate dielectric is exposed that defines where a gate electrode is to be formed; and
electroplating a metallic material upon the select portion of the gate dielectric to form a gate electrode across a portion of the fin structure.

2. The method of claim 1, wherein the gate dielectric has a thickness effective to allow the electroplating thereon.

3. The method of claim 2, wherein the thickness of the gate dielectric is about 0.7 nanometers to about 3.5 nanometers.

4. The method of claim 1, wherein the semiconductor topography further comprises a second semiconductor fin structure laterally spaced from the semiconductor fin structure, and wherein said electroplating also forms the gate electrode across a portion of the second fin structure.

5. The method of claim 1, further comprising, prior to said forming the gate dielectric, forming dielectric spacers upon sidewall surfaces of the semiconductor fin structure and then thermally growing silicon dioxide upon the semiconductor substrate to a thickness sufficient to prevent the substrate from being plated.

6. The method of claim 5, wherein the thickness of the silicon dioxide is about 6 nanometers to about 200 nanometers.

7. The method of claim 5, further comprising removing the dielectric spacers subsequent to said thermally growing the silicon dioxide.

8. The method of claim 1, wherein the gate dielectric comprises silicon dioxide, and further comprising, subsequent to said electroplating, removing the mask followed by selectively depositing an oxide by liquid phase deposition upon the gate dielectric residing on the semiconductor substrate and the fin structure.

9. The method of claim 8, wherein a thickness of the liquid phase deposition oxide is about 2 nanometers to about 10 nanometers.

10. The method of claim 8, further comprising additionally electroplating surfaces of the gate electrode to form metallic spacers over portions of the fin structure while the liquid phase deposition oxide protects the semiconductor substrate and the fin structure from being plated.

11. The method of claim 10, further comprising implanting regions of the fin structure not protected by the metallic spacers to form source and drain junctions.

12. The method of claim 1, wherein the mask comprises a photoresist mold having a slot for defining the gate electrode.

13-20. (canceled)
